(19) United States
(12) Patent Application Publication
(10) Pub. No.: US 2018/0374981 A1
(43) Pub. Date: Dec. 27, 2018

(54) Metamaterial Thermal Pixel for Limited Bandwidth Electromagnetic Sourcing and Detection

(71) Applicant: William N. Carr, Raleigh, NC (US)

(72) Inventor: William N. Carr, Raleigh, NC (US)

(21) Appl. No.: 15/632,462

(22) Filed: Jun. 26, 2017

(51) Int. Cl. H01L 31/12; H01L 31/024; H01L 31/02; H01L 31/0232; H01L 27/16; G01J 5/20; G01N 21/55; G01N 21/27; H05B 3/00

(52) U.S. Cl. CPC H01L 31/12; H01L 31/024; H01L 31/02016; H01L 31/02327; H01L 35/28; G01J 5/20; G01N 21/55; G01N 21/27; H05B 3/009; H01L 27/16

(57) ABSTRACT

A metamaterial pixel providing an electromagnetic emitter and/or en electromagnetic detector operating within a limited bandwidth. The metamaterial pixel is comprised of plasmonic elements arranged within a periodic photonic crystal array providing an electromagnetic emitter and/or an electromagnetic detector adapted in embodiments for operation at selected bandwidths within the wavelength range of visible out to a millimeter. Performance of the pixel in applications is enhanced with nanowires structured to enhance phononic scattering providing a reduction in thermal conductivity. In embodiments multiple pixels are adapted to provide a spectrometer for analyzing thermal radiation or electromagnetic reflection from a remote media. In other embodiments emitter and detector pixels are adapted to provide an absorptive spectrophotometer. In other embodiments one or more of metamaterial pixels are adapted as the transmitter and/or receiver within a communication system. In a preferred embodiment the pixel is fabricated using a silicon SOI starting wafer.

### STATEMENT OF RELATED CASES

This case claims priority to U.S. Provisional Patent Application Ser. No. 62/493,204 filed Jun. 27, 2016. This case is a continuation-in-part of U.S. patent application Ser. No. 15/805,698 filed Nov. 7, 2017. These applications are incorporated herein by reference. If there are any contradictions or inconsistencies in language between these applications and one or more cases incorporated by reference that might affect the interpretation of the claims in this case, the claims in this case should be interpreted to be consistent with the language in this case.

### FIELD OF THE INVENTION

The present invention pertains to apparatus with nanostructured metamaterial structures for sourcing and detection of electromagnetic radiation.

### BACKGROUND OF THE INVENTION

The first practical photonic emitter device manufactured in significant quantities was the incandescent electric light patented by Edison in U.S. Pat. No. 223,898 issued 1880. More recently, the LED patented by Biard and Pittman U.S. Pat. No. 3,293,513 issued 1966 provided another significant innovation in the history of photonic emitters based on a semiconductor non-thermal technology providing emission within a limited bandwidth. Thermal emitters have now been demonstrated with nano-dimensioning comprised of metamaterial structures having deep-submicron critical-dimensioning which also provide emission over a limited bandwidth.

In accordance with a Kirchhoff law, a good electromagnetic emitter is also a good electromagnetic absorber of radiation. A subset of this law is known as the duality principle of electromagnetic antennas. Some thermal emitters and thermal detectors are comprised of metamaterial structures which provide an increase emissivity or absorptivity within a limited bandwidth range

Thermal emitters have been demonstrated with metamaterial structure providing an optical source of limited bandwidth. Thermal detectors have also been reported based on a metamaterial structure providing limited response bandwidth. Selected disclosures of prior art emitters and detectors based on metamaterial structure are presented in the following:

O'Regan, B., et al, “Silicon photonic crystal thermal emitter at near-infrared wavelengths”, Scientific Reports, 5, (2015), 13415 disclose a metamaterial infrared light source comprised of a photonic crystal (PhC) comprised of a single silicon semiconductor layer and heated to provide a narrow band infrared emitter. This metamaterial device is not a plasmonic device since the single semiconductor layer does not support surface plasmonic polaritons at the shorter wavelengths. Burgos et al “Color imaging via nearest neighbor hole coupling in plasmonic color filters integrated onto a complementary MOS image sensor”, ACS Nano, 7, (2013), 10038-10047. disclose a metamaterial plasmonic pixel of extent 6×6 um² comprised of an Al-dielectric-Cu stack providing a filter for visible light.

Wang, H., et al, “Titanium-nitride-based integrated plasmonic absorber/emitter for solar the rmophotovoltaic application”, Photon. Res, 3, (2015), 329-334 disclose a plasmonic metamaterial emitter with an ALD surface area film over an AlN/TiN sandwich with 90% absorptivity for visible light wavelengths.

Wang, H et al, “Switchable wavelength-selective and diffuse metamaterial absorber/emitter with a VO₂ phase transition spacer layer”, App. Phys. Lett., 105, (2014), 071907 disclose a metamaterial infrared absorber/emitter structured as a tri-level sandwich comprising a Bragg resonant first layer overlaying an intermediate layer of VO₂ having an underlying reflecting metal film. When heated, the VO₂ becomes metallic and the absorptance spectral peak vanishes providing a means of switching or tuning a metamaterial structure.

Ghanekar, A., et al, “Novel and efficient Mie-metamaterial thermal emitter for thermophotovoltaic systems,” Optics Express discloses a metamaterial thermal emitter comprised of randomly-disposed tungsten particles within an SiO₂ film matrix over a reflecting tungsten film. The Mie-resonance of the nanoparticles provides a non-plasmonic emitter for visible and near infrared light wavelengths.

Shaban, M., et al, “Tunability and sensing properties of plasmonic/1D photonic crystal”, Scientific Reports, 7, (2017), 41983. disclose a PhC absorber comprised of random metal grains over a sandwich of multiple SiO₂/SiN films. The surface grains provide a plasmonic resonance at the edge of the photonic band-gap (PBG). When heated the emission is expected to be in the visible for this proto absorber design. Readout is obtained by sensing a transmissive beam vectored normal to the plane of the absorber.

Hossain, M. et al, disclose “A metamaterial emitter for highly efficient radiative cooling”, Adv. Optical Mater., (2015), pp 1-4 disclose a metamaterial radiative thermal comprised of a 14-layer patterned combination PhC/PnC arrays. This structure provides an array of surface plasmonic polariton (SPP) elements. This emitter operates within the wavelength range 8-13 um resulting in a net cooling of the array of 117 W/m K.

Liu, X., et al, “Experimental realization of a terahertz all-dielectric metasurface absorber” Optics Express, (January, 2017), 25, 281296 disclose a nonplasmonic terahertz absorber with 97.5% efficiency at a frequency of 1 THz and with a Q=14. The metamaterial structure is comprised of a first layer of patterned Si disks disposed over an unpatterned SiO₂ film.

Zhu, W., et al, “Tunneling-enabled spectrally selective thermal emitter based on flat metallic films”, Appl. Phys. Lett., 106, (2015), 10114 disclose a metamaterial thermal emitter tuned for maximum emissivity at 10 um. The ALD plasmonic surface is excited with photonic tunneling of the evanescent wave from a Fabry-Perot cavity.

Luk, S., et al, in U.S. Pat. No. 9,799,798 disclose a metamaterial infrared light source comprised of a quantum well multi-layer stack. This thermal emitter is comprised of a semiconductor metamaterial having alternating layers of doped semiconductor material and undoped semiconductor material configured to form a plurality of quantum walls. When heated, the metamaterial radiates at a wavelength wherein the effective permittivity is near zero

Inoue, et al, in U.S. Pat. No. 8,017,923 disclose a metamaterial infrared light source comprised of a parallel line Bragg grating without a plasmonic metal film.

Ali in U.S. Pat. No. 9,214,604 discloses a metamaterial infrared light source comprised of a dielectric membrane with laterally spaced metal plasmonic structures.

Araci, et al, in U.S. Pat. No. 8,492,737 disclose a metamaterial infrared light source comprised of a plasmonic stacked metal-dielectric-metal structure of W and HfO₂ layers.

Carr in U.S. Pat. No. 9,817,130 discloses a micro-platform supported by nanowires providing thermal isolation for the platform and structures disposed thereon. This prior art discloses a thermal micro-platform having supports which include nanowires providing improved thermal isolation of the micro-platform. Multi-layer suspended nanowires are disclosed having a first phononic nanostructured layer and in embodiments are further comprised of additional layers of metal films and dielectric films. Phononic structures reduce the thermal conductivity of connecting, support nanowires. A micro-platform is heated or cooled more efficiently because the nanowires provide an increased thermal isolation from a surrounding support platform heat sink.

FIGS. 1-5 depict prior art pixels comprised of micro-platforms configured to provide sensing and cooling functions. FIG. 1 is a plan view depicting a prior art micro-platform 110 with nanowires 214 supported by a surrounding support platform 102. Each nanowire 214 provides support for a portion of the periphery of the micro-platform 110. The micro-platform is suspended over cavity 125. In embodiments a series-connected array of thermoelectric elements 112 may provide either a Seebeck sensing or Peltier cooling function depending on the external circuit connected to 501 and 502. Since the Seebeck and Peltier thermoelectric effects are thermodynamically reversible, Seebeck sensors may also be operated as Peltier coolers by connecting to an external voltage source of appropriate polarity. Another element 504 depicts resistive structures such as a thermistor or heater disposed on the micro-platform 110. In embodiments the micro-platform is comprised of a diffused pn junction diode 872 with external circuit connections provided 503.

FIG. 2 is an illustrative view depicting a prior art nanowire 214 having phononic nano-dimensioned holey structures 104 and 105. These phononic structures reduce the thermal conductivity of the nanowire by phononic scattering or phononic resonance.

FIG. 3 and FIG. 4 depict prior art cross-section views of structures comprising the micro-platform 110 of FIG. 1 with tetherbeams 214 comprised of an active layer 346. In these illustrative depictions the multilayer surrounding structure 340 includes a dielectric film 344, handle wafer 342, bonding film 354 and a header 352. A patterned metallic contact 350 is connected to nanowire 214 in this depiction. The structure of FIG. 3 is comprised of a representative cavity 125 underlying the micro-platform 110 wherein the cavity is created by backside etching of the starting wafer of FIG. 1. In FIG. 4, a cavity 126 underlying the micro-platform 110 is created by topside etching of the starting wafer.

FIG. 5A and FIG. 2 depict additional prior art cross-sectional views of a nanowire first layer 540 having phononic scattering structure. In other embodiments the first layer 540 may be comprised of nano-dimensioned scattering or resonant phononic structures wherein the phonon mean-free-path lengths are generally greater than the distance between the nano-scaled boundaries that comprise the phononic scattering and/or phononic resonant structures. These structures reduce the thermal conductivity of the nanowire. The first layer 510 provides a primary mechanical support for the micro-platform.

The first layer 510 of a nanowire depicted in FIG. 5A also provides an electrical signal connection between on- and off-platform traces and devices. In such structures the separation between phononic scattering structures within the first layer 510 is greater than the mean free path of electrons and holes providing the electrical conductivity.

FIG. 5B depicts a prior art nanowire with two layers. In this embodiment, a second layer 520 of metal is added to provide an increased electrical conductivity. The second layer 520 is an ALD layer, thinner than the first layer, and requires the first layer for structural rigidity. Typical metals used for the second layer 520 include, without limitation, tungsten, molybdenum, platinum, palladium, nickel and titanium. The maximum thickness of patterned second layer 520 films is up to about 500 nanometers.

FIG. 5C depicts a prior art nanowire comprised of three layers wherein an intermediate dielectric film 530 provides electrical isolation between the first layer 510 and a second layer 520. In embodiments, this tri-layer structure provides one or two electrical connections and phononic structuring.

In embodiments, a nanowire is comprised of two layers comprised of a first layer and a dielectric layer providing a means of reducing the mechanical stress across the supported micro-platform. In other embodiments a dielectric layer provides passivation especially during etch processing of the nanowire. The detail clean room processing including film deposition, lithography and etching for creating nanowire structures of these embodiments is well known to those skilled in the art.

### SUMMARY OF THE INVENTION

The present invention discloses an apparatus having a metamaterial thermal pixel physically configured to provide limited bandwidth electromagnetic sourcing and detection. In embodiments, a micro-platform of the pixel is comprised of a metamaterial structure providing an enhancement of electromagnetic emitter or detector performance. A micro-platform having an emitter and/or detector is operated in one or more wavelength bands of interest and is thermally isolated from a surrounding support platform by phononic nanostructured wires.

In some embodiments, the thermoelectric micro-platform includes:
An apparatus comprised of a metamaterial thermal pixel, wherein the metamaterial thermal pixel comprises:
   one or more micro-platforms released from one or more substrates and supported by a plurality of nanowires, wherein each nanowire is partially disposed on both the micro-platform and an off-platform region, the off-platform region surrounding the micro-platform, with each micro-platform further comprised of a metamaterial structure having at least one layer, and further wherein,
   one or more of the plurality of nanowires is physically configured with one or more first layers, the one or more nanowire first layers comprised of phononic scattering nanostructures and/or phononic resonant nanostructures;
   the one or more nanowire first layers provides a reduction in the ratio of thermal conductivity to electrical conductivity, and
   the metamaterial structure physically configured with one or more layers providing one or more of an emitter and/or detector for electromagnetic radiation within one or more wavelength bands.

This invention includes application of the Kirchhoff duality law of photonics. This law states that optical absorptivity is equal to optical emissivity for a given structure. This means that a surface which perfectly absorbs incident electromagnetic radiation is also a perfect emitter. In some embodiments, based on the Kirchhoff duality law, a pixel comprised of a single metamaterial structure is configured and operated as both an emitter and detector based on the Kirchhoff law of photonics. This invention discloses a metamaterial pixel providing, in embodiments, an electromagnetic emitter and/or an electromagnetic detector operating with a limited bandwidth. The limited bandwidths range from ultraviolet to millimeter wavelengths.

In this invention, spectral filtering is provided by metamaterial structure, in embodiments, comprised of one or more layers-of lateral and/or stacked elements. In embodiments, the metamaterial structure may comprise one or more elements selected from among a photonic crystal (PhC), a surface configured to enhance plasmonic polaritons, resonant structures, stacked structure providing electron tunneling, and a heated thermal element. In embodiments, the photonic metamaterial may be comprised of a three-dimensional Fabry-Perot resonant structure or 1- or 2-dimensional Bragg resonant structure. These metamaterial structural elements have a subwavelength critical dimension. These elements range in types from unpatterned ALD films, crossbars, circles, dots, squares, pillars, holes, triangles, partial cavities, simple dipole antennas to more complex elements such as split-ring resonators (SRR). The thickness of the first layer of metamaterial elements ranges from 1 nm to 1000 nm.

The photonic metamaterial structure, in embodiments, is comprised of multiple stacked or laterally disposed films and nanostructures further comprised of metal, dielectric, and particulate structures. In embodiments, the metamaterial structure is comprised of a dielectric or semiconductor layer with embedded nanoparticles providing a superlattice. In other embodiments, the metamaterial films are comprised of a material such as vanadium oxide which undergoes a phase change from dielectric to metallic around the temperature 330K.

In some embodiments, the metamaterial is plasmonic, wherein electric dipole and magnetic dipole modes associated with subwavelength surface arrayed structures overlap in frequency, incident energy is not transmitted nor reflected, but rather is completely absorbed entirely within the metamaterial structure. Or alternatively, in the case wherein the micro-platform is comprised of a heated metamaterial, these modes can provide an almost perfect emitter within the design wavelength bandwidth. These modes exist within the photonic energy bandgap of a metamaterial photonic crystal.

We now describe nanowire structuring and nanowire performance. The effectiveness of phononic structures, providing a reduction of thermal conductivity, is a result of material engineering based on the duality principle in quantum mechanics which stipulates that a phonon can exhibit both wave- and particle-like properties at small scales. All embodiments of the present invention are comprised of a plurality of nanowires physically configured with one or more first layers having phononic scattering and/or resonant structures to reduce thermal conductivity. In this invention, the dominant mechanisms effecting phonon mean free path in nanowires are based on Umklapp scattering, boundary scattering including reflections and resonance effects. In embodiments, a reduction in thermal conductivity provided by a specific phononic structure may involve both scattering and resonance phenomena.

In embodiments, surface structure comprises patterned surface nanodots which advantageously increase boundary scattering and reduce thermal conductivity. In embodiments, phononic scattering structures within the nanowire comprise molecular aggregates and implanted atomic species. In other embodiments, phononic structuring comprises nanostructures disposed at random or within a periodic structure within a nanowire to enhance boundary scattering. The effective mean free path for heat conducting phonons is dependent on the particle-like relaxation time due to multiple scattering of the corpuscular phonons at atomic scale.

Thin films of semiconductor have been physically configured to provide a phononic crystal insulator with a phononic bandgap (see for example, S. Mohammadi et all, Appl. Phys. Lett., vol. 92, (2008) 221905). In some embodiments, wherein thermal conductivity of a nanowire is reduced, an array of phononic structures disposed within or on the surface of a nanowire, provide layers of phononic crystal (PnC). Phononic crystal structuring requires a periodic array of structures such as holes which exhibit elastic (phonon) band gaps. Phononic bandgaps of PnCs define frequency bands where the propagation of heat-conducting phonons is forbidden. Phonon scattering within a PnC-structured nanowire is obtained by physically configuring the nanowire to reduce the phononic Brillouin zone and in some embodiments extend scattering to include successive PnC arrayed layers or interfaces. Nanowires configured with PnC structures can enhance both incoherent and coherent scattering of heat conducting phonons. PnC structures can provide a Bragg and/or Mie resonance of heat conducting phonons. In embodiments of the present invention, a nanowire configured with phononic structures such as PnCs is considered to be a metamaterial nanowire.

In some embodiments, the phononic structure of nanowires may comprise resonant Bragg and Mie resonant structures or scattering structures reducing phonon heat transport. Scattering structures disposed in a periodic array format generally provide an increased reduction in thermal conductivity compared with randomly disposed structures. These structure may comprise embedded particulates, pillars, dots, and holes.

In embodiments, Bragg resonant structures can also be provided in silicon nanowires by implanted elements such as Ar and Ge. Mie resonant structures comprise phonon transport within structures including holes, indentations and cavities within a first nanowire layer. (see M. Ziaci-Moayyed, et al “Phononic Crystal Cavities for Micromechanical Resonators”, Proc. IEEE 24^{th} Intl Conf. on MEMS, pp. 1377-1381, (2011).

An aspect of the present invention is the physical nanowire adaptation providing phononic scattering and/or resonant structures to reduce the mean free path for thermal energy transport by phonons with limited reduction of nanowire electrical conductivity. The dimensions of phononic scattering structures are configured to not limit the longitudinal scattering range for electrons and thereby have limited effect on the bulk electrical conductivity of the nanowire. In this invention, a first nanowire layer is comprised of a semiconductor where the difference in mean free path for phonons and electrons is significant. Typically, in embodiments, the semiconductor nanowires will have electron mean free paths ranging from 1 nm up to 20 nm. The mean free path for phonons that dominate the thermal transport within the nanowire of the present invention is within the range 20 to 2000 nm, significantly larger than for electrons.

In embodiments, the desired phononic scattering and/or resonant structures within nanowires may be created as one or more of randomly disposed and/or periodic arrays of holes, pillars, plugs, cavities, surface structures, implanted elemental species, and embedded particulates. In embodiments, the phononic structuring may comprise patterned surface structures comprised of quantum dots. This structuring, in embodiments, comprises a first layer of nanowires reducing the thermal conductivity.

In some embodiments, the one or more phononic layers of a nanowire is created based on an electrochemical or multisource evaporation process for a semiconductor film deposition and subsequent annealing to provide a porous or particulate-structured film. In other embodiments, a nanowire is selectively ion implanted with a species such as Ar or H to provide scattering structures. Processes for the synthesis of thin films of nanometer thickness with porous, particulate structures, and implanted species is well known to those familiar with the art.

In embodiments, the one or more nanowire first layers is a semiconductor selected from a group including silicon, germanium, silicon-germanium, titanium oxide, zinc oxide, gallium arsenide, gallium nitride, indium phosphide, silicon carbide, titanium nitride, sheets of graphene, nanotubes of carbon and other materials and alloys thereof. In embodiments wherein an increased thermoelectric efficiency is needed, a nanowire layer may be a semiconductor selected from a group including Bi₂Te₃, BiSe₃, CoSb₃, Sb₂Te₃, La₃Te₄, SnSe, ZnS, CdS and alloys thereof.

In embodiments, the nanowire is configured of a sandwich structure comprised of a second layer. This second layer is a metal of nanometer thickness selected from a group including Pt, W. Pd, Cu, Ti, NiCr, Mo and Al providing an increased electrical conductivity. The second layer may be patterned as a film continuing through the nanowire and onto the micro-platform. In embodiments, the second layer of metal connects further onto a thermal heating element disposed on the micro-platform.

In embodiments, a nanowire is a sandwich structure comprised of a third layer of a dielectric material selected from one or more of silicon nitride, silicon oxynitride, aluminum oxide, silicon dioxide and metal oxides to provide electrical isolation and/or a reduction in mechanical stress. The third layer may extend beyond the nanowire and over the micro-platform providing a biaxial compensating stress to reduce overall film stress across the micro-platform. In embodiments, the third layer of dielectric material may be disposed between the first and second layers. In embodiments, the third layer may be disposed onto a second layer. In embodiments, the third layer may be disposed directly on the first layer. In some embodiments, there are more than 3 layers.

In embodiments, one or more pixels are adapted to provide a metamaterial electromagnetic emitter and/or detector. In embodiments, on or more pixels are adapted to provide a spectrometer for analyzing thermal radiation or electromagnetic reflection from a remote media. In embodiments both emitter and detector pixels are adapted to provide an absorptive spectrophotometer. In other embodiments, metamaterial pixels are adapted as the transmitter and/or receiver within a communication system. In the illustrative embodiment, the pixel is fabricated using a silicon SOI starting wafer.

### BRIEF DESCRIPTION OF THE FIGURES

FIG. 1 is prior art plan view depicting a thermal micro-platform.

FIG. 2 is a prior art illustrative view depicting a nanowire with phononic structures providing a reduction in thermal conductivity.

FIG. 3 is a prior art cross-sectional view depicting a micro-platform released from a surrounding support platform using a backside etch.

FIG. 4 is a prior art cross-sectional view depicting a micro-platform released from a surrounding support platform using a topside etch.

FIG. 5A is a prior art cross-sectional view depicting a section of a nanowire comprised of a first layer providing a reduced thermal conductivity.

FIG. 5B is a prior art cross-sectional view depicting a section of a nanowire comprised of a first and second layer in accordance with embodiments of the invention.

FIG. 5C is a prior art cross-sectional view depicting a section of a nanowire comprised of a first, second and third layer in accordance with embodiments of the invention.

FIG. 6A is a plan view depicting arrays of the metamaterial plasmonic elements disposed on the micro-platform in accordance with embodiments of the invention.

FIG. 6B is a plan view depicting additional arrays of the metamaterial plasmonic elements disposed on the micro-platform in accordance with embodiments of the invention.

FIG. 7 is a plan view depicting the pixel configured to provide a metamaterial emitter in accordance with embodiments of the invention.

FIG. 8 is a plan view depicting the pixel configured to provide a metamaterial detector in accordance with embodiments of the invention.

FIG. 9 depicts a standoff infrared analyzer for monitoring the temperature of a remote surface incorporating the pixel in accordance with embodiments of the invention.

FIG. 10 depicts a reflective spectrometer providing reflectance spectra from a remote media incorporating the pixel in accordance with embodiments of the invention.

FIG. 11 depicts an absorptive spectrophotometer incorporating the pixel in accordance with embodiments of the invention.

FIG. 12 depicts a transmitter and receiver within a communication system incorporating the pixel in accordance with embodiments of the invention.

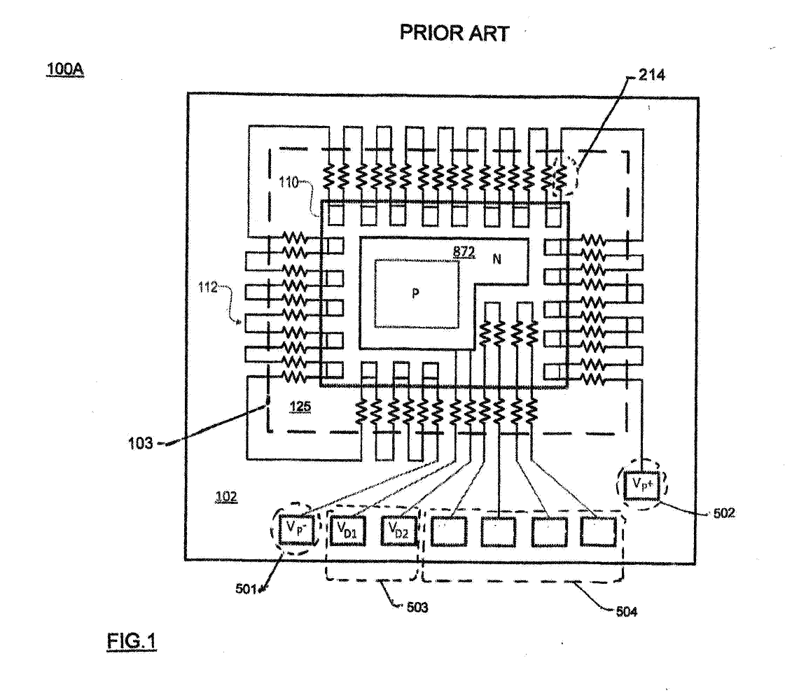

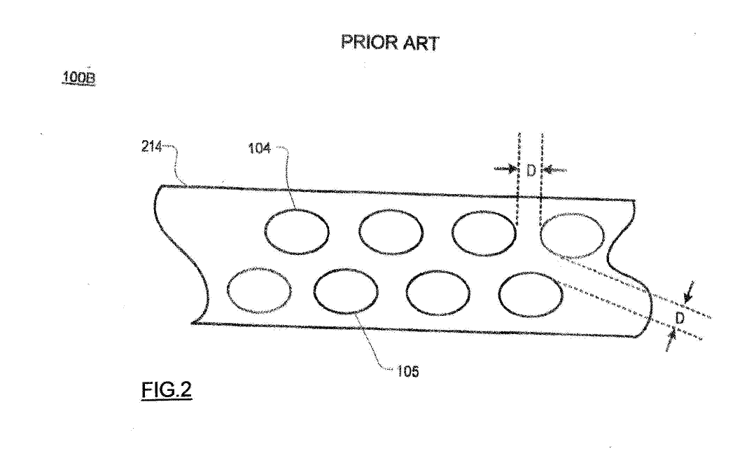

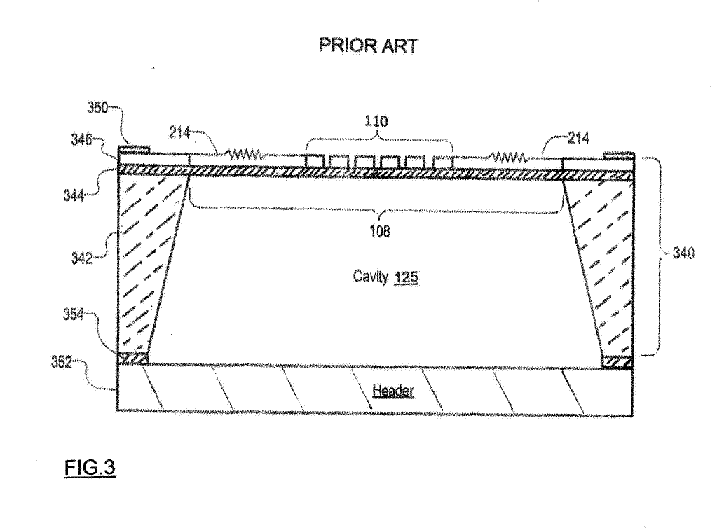

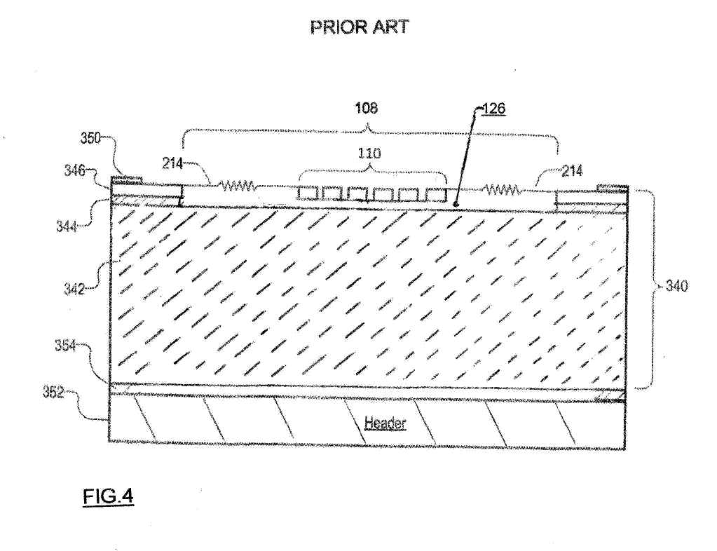

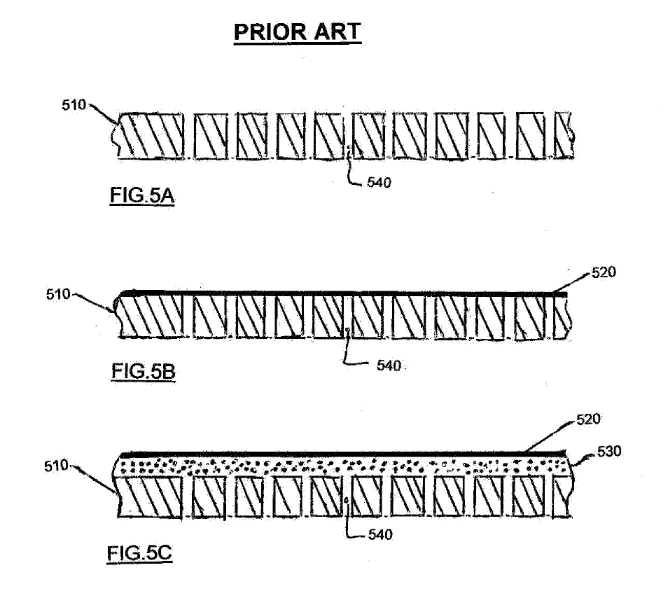

### DETAILED DESCRIPTION

Definitions: The following terms are explicitly defined for use in this disclosure and the appended claims:

“micro-platform” means a platform having a maximum dimension of about 100 nanometers on a side up to about 1 centimeter. “micro-platform comprised of” refers to both the underlying platform structure such as a the patterned active region of a silicon SOI starting wafer in addition to thermal elements and metamaterial structures physically disposed on the platform.”

“metamaterial structure” means a structural component of a pixel providing characteristics not generally found in nature with application as an emitter and/or detector based on structural configurations which affect the movement of photons, electrons, phonons and energy couplings thereof. The metamaterial structure may be non-plasmonic or plasmonic”.

“phononic nanowire” means a suspended nanowire comprised of a phononic structure providing a reduction in thermal conductivity.

“metamaterial pixel” in the present invention means a pixel structurally configured with one or more of phononic crystal, photonic crystal, scattering, superlattice, quantum mechanical tunneling, resonant, and plasmonic structures.

“phononic crystal (PnC)” means a metamaterial structure comprised of periodic subwavelength phononic nanostructure that affects the thermal energy transport of phonons.

“photonic crystal (PhC)” in this invention means a metamaterial structure comprised of periodic subwavelength optical nanostructure that affects the transport of photons.

“surface plasmonic polariton” (SPP) means a surface electromagnetic wave guided along a metametarial patterned surface or ALD film wherein the surface or film has sufficient electrical conductivity to support associated charge motion. In this invention, SPPs within the metamaterial can be excited from an integral photon or electron source such as an internal black body structure, internally-sourced tunneling electrons or from an external photon beam source. A SPP is a type of bosonic quasiparticle.

“nanowire” means a suspended structure providing support for a micro-platform having some structural dimensions of less than 1000 nm.

“emitter” means the metamaterial structure sourcing electromagnetic radiation in the spectral range including ultraviolet, visible light, infrared and into millimeter wavelengths.

“detector” means the metamaterial structure sensitive to incident electromagnetic radiation in the spectral range including ultraviolet light, visible light, infrared, and into millimeter wavelengths.

“thermoelectric device” means any device for conversion of thermal energy into electrical energy or visa versa. This term refers to both temperature control elements and temperature sensing elements.

“temperature control element” means a device for heating such as a heated resistor or a device for cooling such as a Peltier cooler.

“temperature sensing element” means a device for temperature sensing such as a Seebeck thermocouple sensor, thermister, IPTAT, VPTAT, MOST, bipolar transistor or bolometer sensor.

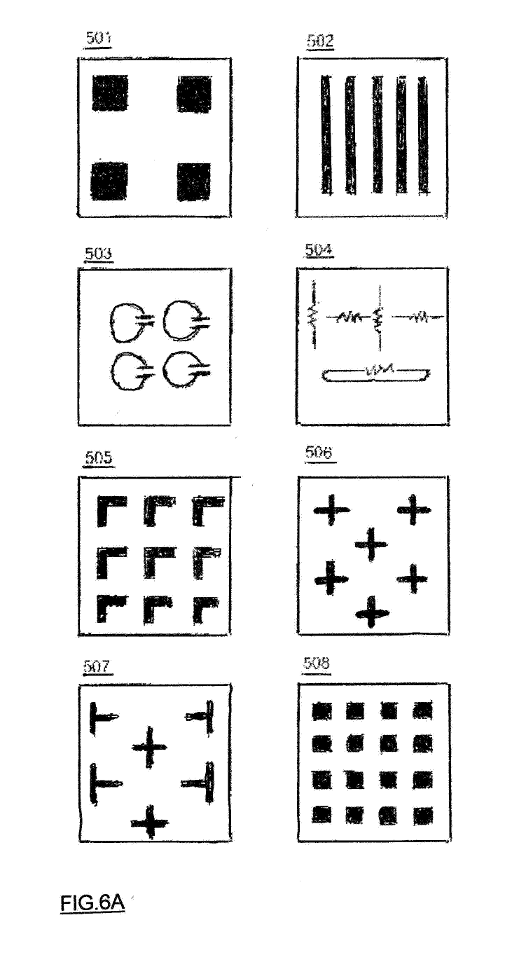

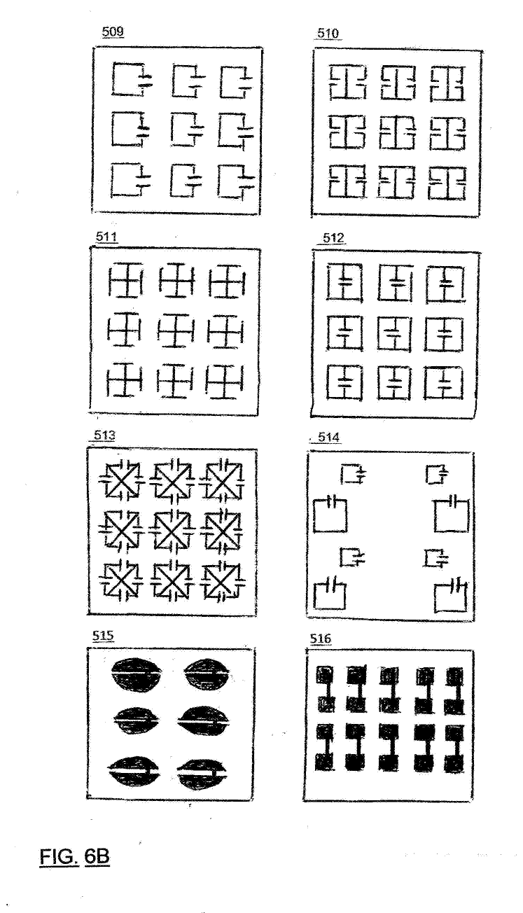

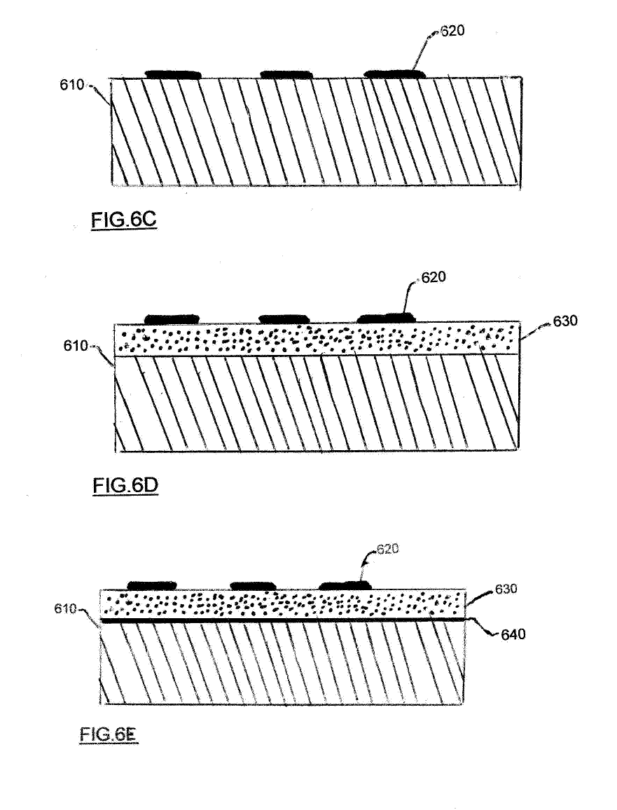

Cross-sectional views depicting metamaterial plasmonic elements as disposed on the micro-platform are presented in FIG. 6A and FIG. 6B. These elements are disposed in a periodic matrix over an underlying dielectric film. In some embodiments, the metamaterial structure includes a metallic film underlying overall. In embodiments, the metamaterial structure is a type of photonic crystal. This metamaterial structuring provides an enhanced emissivity and absorptivity for emitter and detector functions, respectively. Each element supports a local resonant electromagnetic field which couples with fields originating from nearby elements within the larger metamaterial matrix. The entire metamaterial structure, when heated, provides an efficient emitter of radiation, and, when not heated, provides an efficient absorber of incident radiation.

Each panel of FIG. 6A (501-508) shows portions of a larger array of patterned metamaterial filter structure disposed on the micro-platform 610. In this case the micro-platform 110 supports a field confinement adjacent to the surface elements 620. The individual elements 501-508 are of subwavelength dimension (as referred to free space wavelength). The principal wavelength of filter 501 is generally lower than that of filter 508. Panel 502 shows a 1-D Brag grating structure which is polarization sensitive. Panel 503 shows split-ring resonant SRR elements which are typically used in filters with center frequencies in the very long wave infrared region. Panel 504 presents polarization-sensitive simple dipoles and a folded dipole resonant antenna forming a cell within a larger periodic plasmonic array. All panels except 504 and 507 each provide a single, primary bandwidth filter band while panels 504 and 507 are characterized by multiple primary operational wavelength bands. Secondary bands are generally observed which derive from minor resonances associated with specific dimensions and couplings beyond nearest neighbor elements. Surface plasmonic coupling generally involves polariton waves associated with individual resonant elements.

FIG. 6B is a plan view depicting additional arrays of metamaterial plasmonic elements. Panels 509 through 516 present portions of periodic arrays comprised of split-ring resonators. Panel 514 depicts an array portion providing filter with at least two primary wavelengths.

FIG. 6C is a cross-sectional view depicting metamaterial plasmonic elements 620 disposed on portions of a micro-platform 610 in FIG. 6A and FIG. 6B. The metal film is patterned to provide raised, pillar-like structures above the micro-platform 110.

Metal films are chosen as the surface element 620 in most embodiments for operation in the visible, near infrared, and long-wave infrared wavelength region because metals provide a high plasma frequency and an increased density of electrons compared to a semiconducting structural element. In embodiments, semiconductor surface plasmonic structures such as are depicted in FIGS. 6A and 6B can provide operation at mid-infrared and longer wavelength regions.

FIG. 6D is a cross-sectional view depicting plasmonic elements 620 disposed on the micro-platform 610 with an intermediate dielectric film 630. This is typically a film selected for low loss at the wavelength of interest and in some embodiments a film selected to reduce overall stress across the micro-platform. The dielectric film 630 is generally of thickness ranging from 30 nm to 1 micrometer.

FIG. 6E is a cross-sectional view depicting surface plasmonic elements 620 disposed with three films disposed on the micro-platform 610. This tri-level film sandwich is comprised of an intermediate dielectric film 630 and a metallic film 640 of typically of thickness of 1 micrometer or less. In embodiments, the metallic film provides increased confinement of the electromagnetic field associated with the surface plasmonic structures with an accompanying increase in overall emissivity or absorptivity.

The metallic surface and reflecting structures in many embodiments are comprised of metals to reduce losses at shorter infrared wavelengths. A preferred metal for performance over a wide range of wavelengths is Ag, W, Pd, Pt, Ni, Al, and Ti. In some non-CMOS embodiments, the surface metal is Au. The patterned metallic metamaterial elements are typically of thickness in the range of 1 nm to 1000 nm.

In other embodiments, nonmetallic arrayed surface elements 610 depicted in FIG. 6A and FIG. 6B are suitable for pixels adapted for operation in the very longwave infrared regions out to about 1 mm. At these wavelengths a semiconductor can provide lower loss compared with metallic structures. In these embodiments, the surface film element 620 is selected to provide a dielectric constant compared with an underlying film 620 of lower dielectric constant depicted in FIGS. 6A-6E. 6. In embodiments, these structures may be raised areas, pillars, cavities, holes or structures embedded within a dielectric film.

Tri-level metamaterial filters of FIG. 6E based on the panels of FIG. 6A and FIG. 6B in many cases provide an electromagnetic bandwidth quality factor Q of 10 or higher. In embodiments, the multi-layering concept of FIG. 6E is extended to provide more than three layers. Appropriate stacked structuring with vertical plasmonic coupling between metallic elements at different stack levels provides a 3-D metamaterial structure. These 3-D stacked metamaterial structures can be optimized to provide a further narrowing of the bandwidth of the metamaterial filter with an accompanying increase in the quality factor Q.

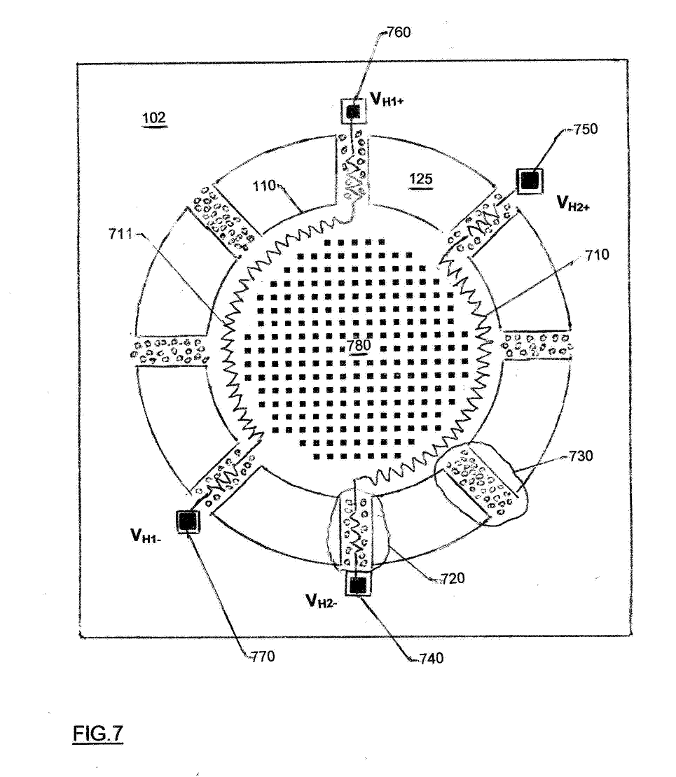

FIG. 7 is a plan view depicting a semiconductor chip adapted to provide a metamaterial emitter. Thermoelectric control elements disposed on the micro-platform 110 are resistive heaters (710 and 711). This embodiment a micro-platform 110 provides a uniform stress into the platform and generally permits fabrication of larger micro-platforms over the underlying cavity 125. The micro-platform 110 is supported by nanowires 730 comprised of a level 1 film and nanowires 740 comprised of a level 1 film covered with a level 2 metal film. The nanowires are tethered onto surrounding support platform 102 which provides a thermal heat sink. The micro-platform 110 is heated by a first heating element 710 disposed between bonding pads 740 and 750. In this embodiment a second heating element structured similar to the first heating element, is contacted through bonding pads 760 and 770 disposed on the surrounding support platform 102.

In embodiments comprising the emitter of FIG. 7, a first level of the metamaterial structure may be selected, without limitation, from among the structural options of FIG. 6. In the embodiment of FIG. 7, the micro-platform formed of the active layer from a silicon SOI starting wafer is heated to a temperature of 400° C. and higher when a high temperature metal such as tungsten is used on the nanowires and micro-platform. If a lower temperature metallization such as aluminum is used, the maximum operational temperature is limited to around 400° C. In other embodiments, a pixel similar to that of FIG. 7 comprising a semiconductor active layer such as silicon carbide or gallium nitride and with dielectric passivation films of silicon nitride permits heating of a micro-platform to temperatures over 1000° C.

Tungsten and aluminum films are deposited using a DC magnetron tool. Any dielectric film chosen is generally deposited by RF sputtering. Patterning of these thin films is accomplished using a resist such as patterned PMMA with a lift-off process. Other patterning techniques are used with thicker films. Backside etch to form the cavity 125 is accomplished with DRIE or with patterned TMAH or KOH at an elevated temperature. Topside formation of the cavity 126 is accomplished using a hot vapor HF etch and with a patterned passivation layer of material such as Si₃N₄ protecting certain topside areas as desired.

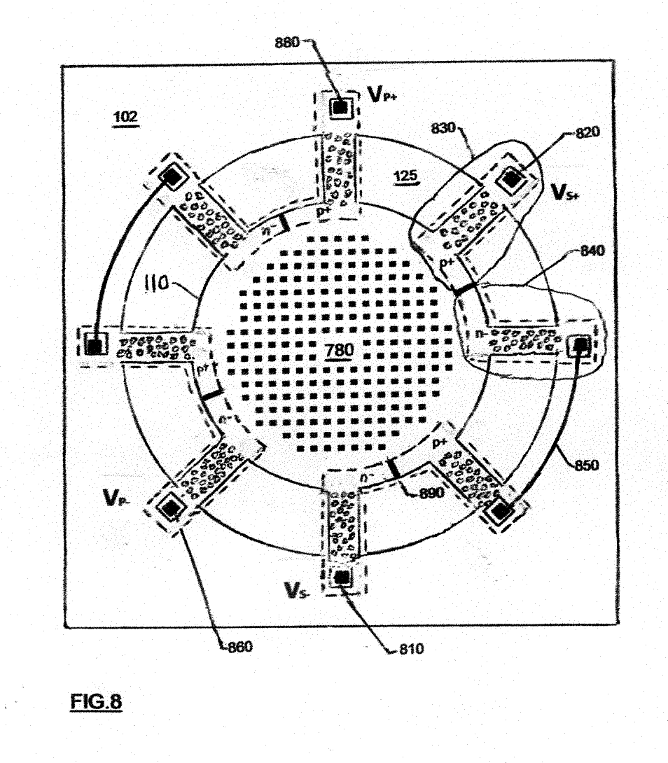

FIG. 8 is a plan view depicting a semiconductor chip adapted to provide a metamaterial detector. In this illustrative embodiment, the detector is comprised of a Seebeck sensing element and a Peltier controlled-cooling element. The detector pixel is comprised of a micro-platform 110 disposed over cavity 125. Nanowires of types 820 and 840 support the micro-platform 110 and are tethered onto the surrounding micro-platform 102. Nanowires of type 820 are comprised of heavily doped p+ and n-couplings 840 connected in series to provide a thermocouple array with couplings disposed on the micro-platform 110 and the off-platform heat sink area 102. The thermocouple may be operated in either a Seebeck sensor or Peltier cooling mode. The thermocouple is comprised of a metallic on-platform ohmic connection and an off-platform interconnecting trace 850. The two thermocouples are electrically connected between bonding pads 810 and 820 disposed on the surrounding support platform 102. The thermocouples sense the minute differential temperature difference between the micro-platform 110 and the surrounding heat sink 102 resulting from absorbed incident radiation into the metamaterial structure 780.

It will be noted the Seebeck sensor array is depicted in FIG. 8 with only two thermocouples. In embodiments, the micro-platform is populated with over 2000 series-connected thermocouples, providing an increase in overall pixel detectivity D* and responsivity (Volts/Watt) for pixel operation as a detector. In embodiments comprising the detector of FIG. 8, a metamaterial structure may include, without limitation, the first layer structure options of FIGS. 6A-6D.

In many embodiments, including the embodiment of FIG. 8, the micro-platform 110 is formed of the high resistivity active layer of a starting silicon wafer having a resistivity of over 1000 Ohm-cm. The heavily doped thermocouple regions are diffused directly into the high resistivity micro-platform 110. Sensed signal loss due to the shunt effect of parasitic resistance in the high resistivity areas is designed to be minimal. The heavily doped thermocouple regions of p+ type 820 and n− type 830 semiconductor are typically formed by diffusion from a patterned spin-on glass formed with boron or phosphorus in the illustrative silicon process embodiment. For detector pixels operated at temperatures of less than 400° C., DC sputtered aluminum is used for metallization. Selected ALD dielectric films are generally deposited by RF plasma sputtering or physical evaporation. Patterning is generally accomplished using a PMMA or similar resist with micro-dimensioning obtained with e-beam lithography or optical lithography as appropriate.

In the illustrative embodiments of FIG. 7 and FIG. 8, the plasmonic absorber 780 can be identical for both the emitter of FIG. 7 and the detector of FIG. 8. The use of a certain commonality in the cleanroom process for both the emitter pixel and the detector pixel embodiments permits a lower cost production processing.

In embodiments, the emissivity/absorptivity of the metamaterial structure can be enhanced by growing or depositing carbon nanotubes (CNT), especially vertical multiwall carbon nanotubes (VWCNT) or graphene. Carbon nanotubes are grown typically using an acetylene precursor in a CVD reactor. In embodiments, graphene is generally deposited as a random mesh over the metamaterial.

In embodiments, the pixel is mounted in a package backfilled with a gas of low thermal conductivity such as Xe, Kr or Ar. This reduces the parasitic loss due to thermal conductivity of atmosphere between the micro-platform and the surrounding heat sink. In embodiments, the pixel is disposed within a vacuum package for the purpose of reducing heating or cooling of the micro-platform due to undesirable convective and conductive heat dissipation.

In some package embodiments, the pixel is sealed in an oxygen environment. An additional resistive heater is disposed on the micro-platform in thermal contact with a gettering material. When the additional resistive heater is powered the gettering material is activated and an outgassing of the pixel environment is achieved providing a vacuum.

### Example 1

### Multi-Wavelength Pyrometer

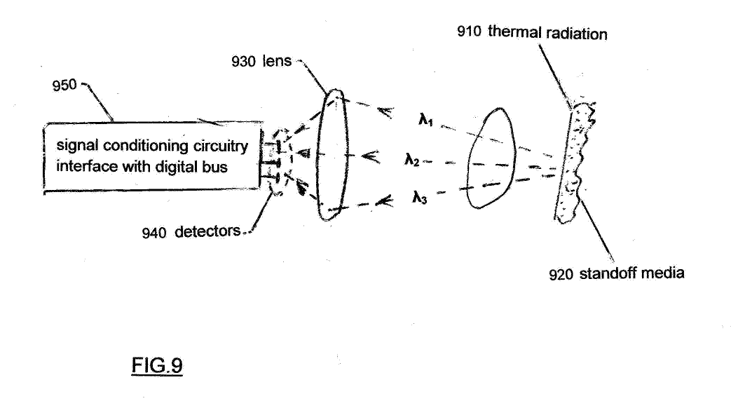

FIG. 9 depicts an apparatus comprised of multiple detector pixels adapted as a standoff infrared analyzer monitoring the temperature of a standoff media 920. Multiple detectors 940 are sensitive to separate wavelength bands of thermal radiation 910 emitted from standoff media 920. Optics 930 focus the radiation 910 from the remote media 910 onto the detectors 940. In this embodiment, signal conditioning circuitry 950 with an interface to a digital bus permits a determination of the temperature of a standoff media based on differential spectral analysis of the emitted thermal radiation and an estimate or calibration of thermal emissivity of the standoff media 920. In embodiments, this adaptation is implemented with multiple detectors providing a multi-wavelength pyrometer.

### Example 2

### Reflective Spectrometer

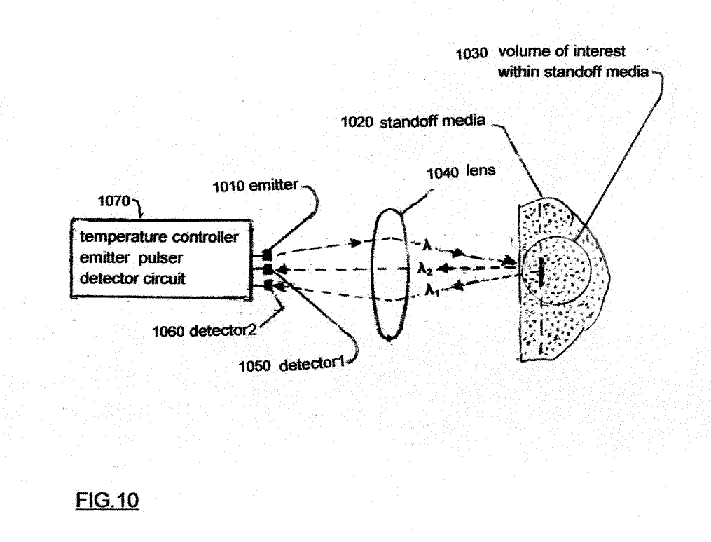

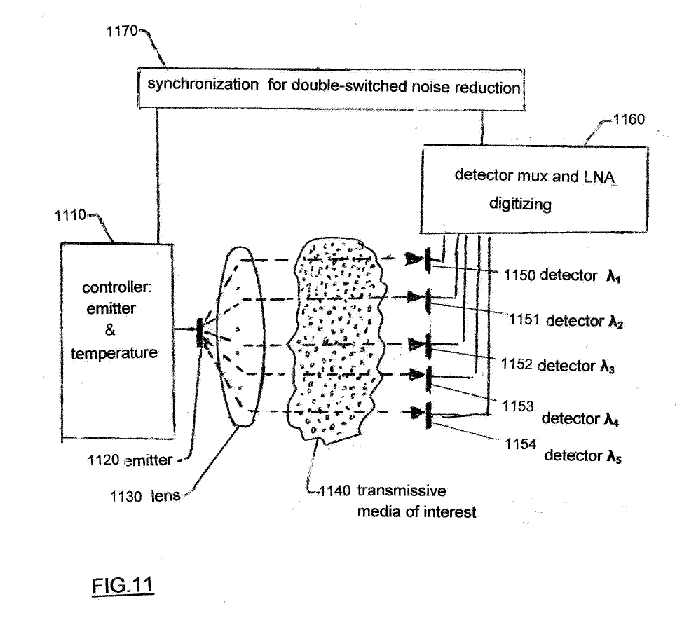

FIG. 10 depicts the pixel configured to provide a reflective spectrometer for spectral analysis of reflectance from standoff media. The spectrometer is comprised of both an emitter 1010 which illuminates a standoff media through focusing optics 1040 and detectors 1050 and 1060 monitoring the return beam. The emitter and detector pixels are comprised of metamaterial plasmonic devices. The reflectance 1030 from the standoff media 1020 is determined by the surface and near surface permittivity at various depths from the surface of the standoff media 1020. The detectors 1050 and 1060 are structured to provide sensitivity over selected wavelength bands within the emitted spectrum of the emitter 1010. The emitter and detectors are disposed on at least two different micro-platforms within one or more pixels. The spectrometer is comprised of circuits 1070 for powering the emitter and providing signal conditioning for the detectors. In application the spectrometer may provide monitoring of spectral reflectivity of processed food, agricultural products and epidermal human skin or tissue.

### Example 3

### Absorptive Spectrometer

FIG. 11 depicts the pixel adapted to provide an absorptive spectrometer in this illustrative embodiment comprised of a broadband emitter 1120 and detector pixels 1150-1154 with an analyzing beam transmitted through a media of interest 1140. Optics 1130 is used to collimate the broadband emitted beam through the media 1140. Controller 1110 powers the temperature dynamics of the micro-platform of emitter 1120. Multiple detectors 1150-1154 detect the beam modulated by its traverse through the media of interest 1140. In embodiments, the emitters and detectors are comprised of plasmonic or nonplasmonic metamaterial devices. The detectors 1150-1154 are disposed on separate micro-platforms within one or more pixels. Control circuit 1110 implements a synchronized sampling link 1170 providing double-switched sampling of each detector 1150-1154. This synchronized sampling reduces noise originating from sources external to the emitter 1120, media 1140 and detectors 1150-1154.

### Example 4

### Infrared Communication System

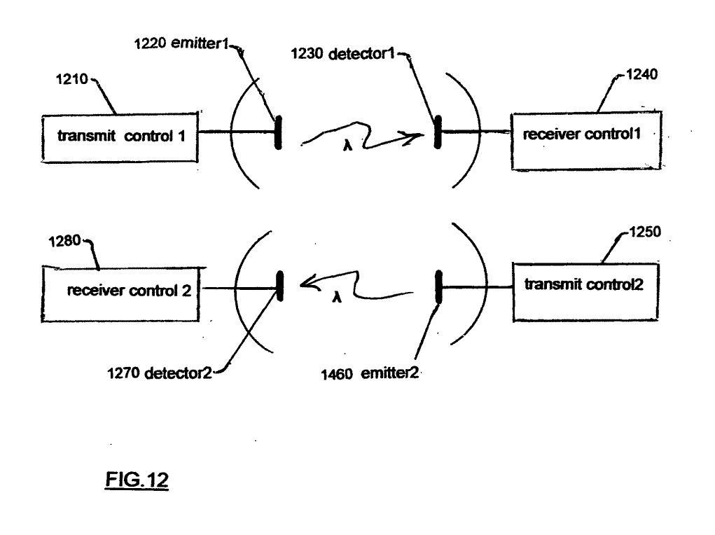

FIG. 12 depicts a full duplex communication system comprised of a forward path emitter1 1220, detector1 1230 return path emitter2 1250 and detector2 1270. Transmit control1 and transmit control2 modulate the intensity of respective emitters 1220 and 1250. Receiver control1 and receiver control2 provide signal conditioning for respective detectors 1230 and 1270. The emitters and detectors are comprised of metamaterial plasmonic devices. In other embodiments, the system adapted with additional metamaterial thermal structures provide communication over multiple wavelength bands and with communication protocols such as FSK, FHSS and DSSS protocols.

It is to be understood that although the disclosure teaches many examples of embodiments in accordance with the present teachings, many additional variations of the invention can easily be devised by those skilled in the art after reading this disclosure. As a consequence, the scope of the present invention is to be determined by the following claims.

1. An apparatus comprising a metamaterial thermal pixel, wherein the pixel comprises:
a thermal micro-platform, the thermal micro-platform having a support layer that is suspended by nanowires at a perimeter thereof, and an active layer disposed on a portion of the support layer;
an off-platform region, the off-platform region surrounding the micro-platform;
a plurality of the nanowires comprised of a first layer having phononic scattering and/or phononic resonant structures physically adapted to reduce thermal conductivity, and
wherein one or more of the thermal micro-platform is comprised of an arrayed metamaterial structure providing one or more of an emitter and/or detector for electromagnetic radiation.

2. The apparatus of claim 1 wherein the thermal micro-platform is comprised of a temperature control element further comprised of one or more of a resistive heater or a Peltier thermoelectric cooler.

3. The apparatus of claim 1 wherein the thermal micro-platform is comprised of a temperature sensing element further comprised of one or more of Seebeck thermoelectric devices, a thermistor, and a subthreshold MOST, PTAT bandgap diode.

4. The apparatus of claim 1 wherein one or more of the thermal micro-platform is comprised of a periodic array of metallic, dielectric or semiconductor elements shaped variously as, without limitation, squares, crossbars, circles, dipole antennas, and split ring resonant (SRR) structures.

5. The apparatus of claim 1, wherein the one or more of the thermal micro-platform comprises a reflecting metallic film providing an increased reflective plasmon confinement at the wavelength band or bands of interest.

6. The apparatus of claim 1 wherein the one or more of thermal micro-platform is comprised of one or more composite levels of plasmonic resonant structures providing operation within one or more wavelength bands of interest.

7. The apparatus of claim 1 comprising a plurality of thermal micro-platforms, each platform having one or more of the emitter and/or the detector.

8. The apparatus of claim 1 wherein the first layer of the plurality of nanowires has phonon mean-free-paths greater than the distance between atomic- or nano-scaled boundaries, providing a means for reduction in thermal conductivity.

9. The apparatus of claim 1 wherein the first layer of the plurality of nanowires is a semiconductor active layer.

10. The apparatus of claim 1 wherein the thermal micro-platform and the nanowires are comprised of the active layer of a silicon SOI starting wafer.

11. The apparatus of claim 1 wherein the plurality of nanowires is comprised of a first and second layer, the second layer comprising a metal selected from the group, without limitation, tungsten, palladium, platinum, molybdenum, and aluminum providing an electrical connection of increased electrical conductivity.

12. The apparatus of claim 1 wherein the plurality of nanowires is comprised of a third layer further comprised of a dielectric selected from the group comprising, without limitation, silicon nitride, silicon oxynitride, aluminum oxide, and silicon dioxide, and further wherein the dielectric provides a reduction of stress across the micro-platform.

13. The apparatus of claim 1 wherein the active layer is a semiconductor comprised of, without limitation, silicon, germanium, silicon-germanium, gallium arsenide, gallium nitride, indium phosphide, silicon carbide and alloys thereof.

14. The apparatus of claim 1 wherein the one or more thermal micro-platform is covered with random matrices of carbon nanotubes or graphene disposed to provide a further enhancement of emissivity or absorptivity.

15. The apparatus of claim 1 wherein the pixel is maintained under vacuum and is comprised of a resistive heater having a gettering material providing a means of degassing within the vacuum volume.

16. The apparatus of claim 1 wherein the one or more of the thermal micro-platform is adapted to provide a standoff spectral reflectance analyzer for a remote media including agricultural soils and food products.

17. The apparatus of claim 1 wherein the thermal micro-platform is adapted to provide a standoff temperature sensor for monitoring the temperature of a remote media.

18. The apparatus of claim 1 wherein the one or more thermal platform is adapted to provide a spectrophotometer for spectral analysis wherein an electromagnetic beam is sourced by the emitter, transmitted through or reflected from an analyte comprised of a gas, vapor, particulate or surface, and detected by the detector.

19. The apparatus of claim 1 wherein the emitter and detector provide one or more of a transmitter and/or a receiver within an infrared communication system.

20. The apparatus of claim 1 wherein the emitter and/or detector operate within one or more wavelength bands of limited bandwidth, the wavelength bands comprised of visible light, infrared and millimeter wavelengths.
